(19) United States
(12) Patent Application Publication
(10) Pub. No.: US 2006/0166518 A1
(43) Pub. Date: Jul. 27, 2006

(54) Subtractive-Additive Edge Defined Lithography

(75) Inventor: Clarence John Dunnrowicz, Santa Cruz, CA (US)

Correspondence Address: Clarence Dunnrowicz, 8901 Empire Grade Rd., Santa Cruz, CA, 95060, US

(73) Assignee: Clarence John Dunnrowicz, Santa Cruz, CA (US)

(21) Appl. No.: 11/308,527

(22) Filed: Apr. 2, 2006

(51) Int. Cl. H01L 21/425

(52) U.S. Cl. 438/942; 438/531

(57) ABSTRACT

A subtractive-additive, differential lithography technique capable of generating sub-half micron geometries using a larger feature parent mask is described. The basic technique is defect tolerant with respect to electrical shorting, can fabricate T-shaped conductors of optimum geometry to minimize electrical RC time constant, and can be extended to very small, dense geometries by utilizing interference lithography or nano-imprint parent masks. Demonstration fabrication examples include a Surface Acoustic Wave (SAW) transducer, Field Effect Transistor (FET), and grating interconnection method.

Conceptually, structure fabrication can be simplified into the basic elements of addition, subtraction, and reshaping. Noteworthy examples include the Golden Gate bridge, Michelangelo's David, and the ubiquitous nano-imprint molding of CD/DVD disks, respectively.

Modern society is largely based upon the creative and highly refined application of these fundamental processes to the miniaturization and planarization of the basic transistor or switch. Pursuit of this goal by the direct fabrication of these microscale elements has resulted in rapid progress and an empirical scaling model commonly referred to as Moore's Law. It is the scope of this invention to demonstrate that micro-scale elements can also be realized by appropriately combining the indirect, differential technique of sequential subtractive and additive processes on larger scale elements. Inventor/Assignee: Clarence Dunnrowicz

### REFERENCES

Henry I. Smith, “Fabrication Techniques for Surface Acoustic Wave and Thin Film Optical Devices”, Proceedings of the IEEE, Vol. 62, No. 10, October 1974
D. C. Flanders and N. N. Efremow, “Generation of <50 nm Period Gratings using Edge Defined Techniques”, J. Vac. Sci. Technol., B1 (4), October-December 1983
D. C. Flanders and Henry I. Smith, “Surface Relief Gratings of 320 nm Period Fabrication Techniques and Influence on Thin Film Growth”, J. Vac. Sci. Technol., 15(3), May/June 1978
T. A. Savas et al, “Achromatic Interference Lithography for 100 nm Period Gratings and Grids”, J. Vac. Sci. Technol., B 13(6), November/December 1995
Marc J. Madou, “Fundamentals of Microfabrication: The Science of Miniaturization”, 2^{nd} Edit., CRC Press, 2002, ISBN 0-8493-0826-7

### BACKGROUND OF THE INVENTION

1. Field of Invention

This invention is directed to the fabrication micro-scale planar elements. Specifically, it is directed toward the fabrication of sub-half micron, T-shaped metal structures on planar substrates commonly utilized for semiconductor and optical devices. Generally, the method can also be utilized to double the spatial periodicity of a nano-scale element array. This differential lithography technique can provide a reduced capital cost approach to state of the art micro-scale devices, with only nominal increase in basic labor process steps relative to standard techniques.

2. Description of Related Art

The direct replication of high resolution planar elements of arbitrary shape generally entails using lithographic exposure sources of comparable wavelength dimensions with associated depth of focus and field size restrictions. It is also generally desirable to have a patterning technique which is relatively insensitive to substrate topographical and reflective variations. Substrate re-planarization techniques and appropriate choice of photoresist thickness, plus anti-reflection coatings (ARC), are commonly employed to address these requirements when using partially coherent reduction steppers.

The direct generation of high resolution planar elements of highly periodic nature can utilize laser interference lithography (IL) . Depth of focus and field size restrictions are significantly reduced, albeit carefull exposure setup is required for consistent phase stability of the interfering beams to insure image contrast. Several ingenious active feedback phase stabilization techniques have also been utilized. ARC are generally employed to control substrate reflections, but uneven topography remains a challenge.

Narrow wavelength steppers typically replicate a multiple-step copy of a primary mask reticle serially generated by e-beam, whereas IL has the unique distinction of generating a primary in-situ mask over a very large field. However, stitching errors aside, at very small feature sizes within scope of each regime, there is some commonality with the use of phase-shifting masks with steppers, and the employ of phase gratings with ultraviolet semi-coherent sources for IL. The utilization of lasers with steppers combined with phase shifting masks illustrates the basic optical restrictions of trying to reduce an arbitrary reticle of finite size with curved wavefronts, versus that of the spatially defining pinhole aperture and planar wavefronts of interference lithography.

In any case, the remarkable rapid technical refinement of optical lithography continues to provide the foundation for exploiting the potential of material science in the nano-scale regime.

### BRIEF SUMMARY OF THE INVENTION

A lithographic image formed on the substrate surface is seldom the desired end product, but rather serves as an intermediate mask for further processing. One measure of the accuracy or dimensional fidelity of a given process step is to consider its reversibility. Ideally, sequential subtractive and additive process steps should yield a negligible difference. In practice, the non-zero difference is termed process bias, and its control is of paramount importance. Clearly, the bias is proportional to the amount of subtracted and added material, and for lateral dimensions in the nano-scale regime, small bias generally dictates the processing of very thin films (VTF). Furthermore, the specific processing method of a (VTF) should exhibit high selectivity with respect to the overlying mask and the underlying substrate. The interface adhesion between layers should be excellent. The substrate or component elements should not be damaged or subject to galvanic corrosion effects. The (VTF) grain structure should be nearly amorphous to avoid preferential roughening.

In practice, many lithography applications utilize a tri-level processing sequence in which the primary imaged layer is used to process a thin, intermediate mask overlying a planarizing and anti-reflection coating. Therefore, another requirement if (VTF) is to serve as an intermediate masking layer is that it also display a very high selectivity to any subsequent processing steps. Lastly, it is also desirable that (VTF) material be readily available, and facilitate mask-substrate alignment.

Within scope of this invention it has been determined that a 10% titanium-tungsten (TiW) sputtered layer of approximately 20-30 nm uniquely meets above (VTF) requirements. This material is commonly utilized as a metal contact and diffusion barrier. It displays good adherence due to the titanium content, has small grain size, and most notably can be etched (subtracted) using essentially oxizidized water or hydrogen peroxide at room temperature. In addition, the (Ti,W) metal oxides display very high selectivity in oxygen plasmas, permitting precise patterning of underlying organic layers typically used in tri-level patterning schemes. Although not fully transparent, a TiW layer of this thickness is semi-transparent or partially absorbing, helping to reduce substrate reflections.

The combination of TiW as (VTF) and excellent selectivity of chemical etching allows the subtractive—additive bias to be very small. In essence, the (VTF) bias undercut in a stagnant etch solution is diffusion limited and highly uniform. Although the chemically etched TiW sidewall has in principle an isotropic profile, it has minor impact for a (VTF) which has high etch selectivity in subsequent process steps.

The selection requirements of the (VTF) for the additive step following etching of TiW layer are that it must exhibit good adherence, a fine grain structure, well behaved evaporation properties, and preferably be in common use. One material that fulfills these requirements is titanium. It is evaporated onto the surface at normal incidence to a thickness less than the TiW layer thickness. Liftoff of the original TiW PR mask reveals the differential bias undercut gap. It should be noted that a defect in the original TiW PR mask such as a hole, dirt particle, or incomplete PR development will typically not result in shorting between TiW and Ti layers. Thus the SAEDL technique offers a defect tolerant method of generating a sub-micron spaced electrode structure that is robust to electrical shorting problem.

In one embodiment of this invention, this robust feature can be very usefull in decreasing the operational bias of a device while maintaining a high process yield as illustrated in FIG. 3. As illustrated, aluminum 10, 11 metal replaces the TiW/Ti 1 masking layers shown in FIGS. 1,2, and polyimide layer 4 is omitted for fabricating a Surface Acoustic Wave (SAW) transducer. Similarly, FIG. 4 illustrates SAEDL technique applied to electrical interconnection of fine grating lines formed by interference lithography (IL) without the need for e-beam or focused ion beams.

The selection requirements for the underlying organic planarizing layer are that it exhibit good adhesion to the substrate, exhibit solvent selectivity with respect to PR liftoff, etch cleanly at low plasma potential, be readily strippable in a solvent compatible with metallized III-V compound substrates, and not undergo microscopic thermal deformation. One preferred class of organic compounds satisfying these requirements are thermoset polyimides. It has been determined that such material can be pre-baked to provide required thermal and chemical robustness, and yet remains readily strippable on sensitive substrates.

### BRIEF DESCRIPTION OF THE DRAWINGS

FIG. 1 is a section view illustrating the basic subtractive—additive edge defined lithographic (SAEDL) processing sequence using (TiW/Ti) masking films to generate a liftoff T-shaped metal conductor.

FIG. 2 is a top view SAEDL fabrication sequence for the unit cell of a multiple T-gate Field Effect Transistor (FET).

FIG. 3 is modified SAEDL fabrication example of surface acoustic wave transducer on a quartz substrate. Unequal line-space ratio can increase harmonic coupling efficiency, and also reduce fundamental transducer acoustic scattering, an important parameter for high Q resonators.

FIG. 4 is a top view SAEDL fabrication sequence for the electrical interconnection of micro-scale grating lines generated by interference lithography.

### DETAILED DESCRIPTION OF PREFERRED EMBODIMENTS

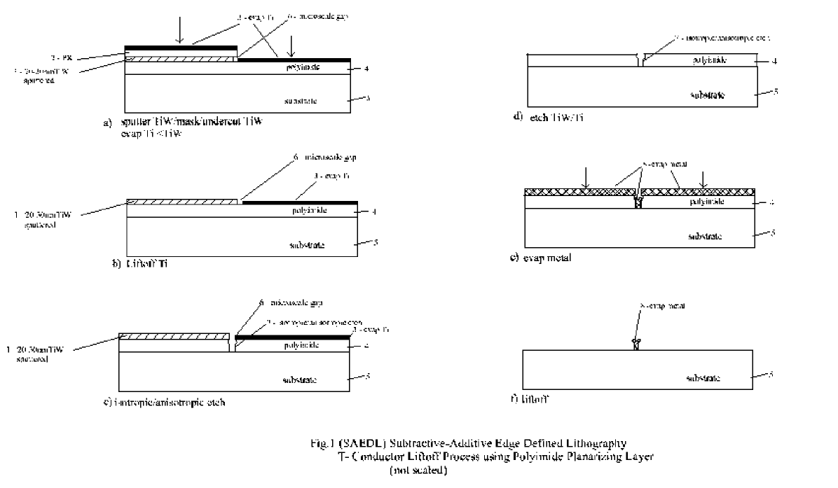

FIG. 1 is a section view illustrating the basic subtractive—additive edge defined lithographic (SAEDL) processing sequence with (TiW/Ti) masking films to generate a liftoff T-shaped metal conductor using a polyimide planarizing layer.

Follow polyimide 4 layer manufacturer recommended procedure for substrate 5 preparation. This typically involves hydrocarbon contamination removal and a desorption bake prior to application of an adhesion primer. Try to choose a polyimide 4 that approximately matches substrate 5 thermal expansion, but it is not critical as it is typically kept thin and not fully cured for this application. Viscosity and spin speed will depend on desired final dimensions of T-shaped conductor 8, etc. Dupont Pyralin series or similar have given good results. After spin, a prebake of approximately 100 deg.C. for 60 min., followed by 200 deg.C. for 60 min. in nitrogen has been found to give satisfactory stabilization.

Immediately load substrates 5 into load lock sputter system. If substrates 5 must be stored, it is best to use vacuum oven at ˜80° C. Re-bake substrates −10 min. @150 deg.C. if stored in nitrogen cabinet. Coat substrates with approximately 30 nm TiW 1. Do not bias sputter TiW 1, as any surface inter-mixing can lead to polyimide 4 etch complications. However, a brief (30 sec) in-situ Ar sputter etch before deposition is permitted. Pay attention to re-deposition cross-contamination of polyimide 4 surface. RF or magnetron sputtered TiW is acceptable. Monitor TiW 1 specific sheet resistivity as indirect control of background doping.

It is best to spin coat substrates 5 as soon as removed from vacuum chamber. Approximately 0.5 u PR 2 should suffice. Bake 90 deg.C. 60 min. , expose mask, develop, brief plasma ash. Flood expose PR 2, let sit approximately 15 min., bake 90 deg.C./5 min., 135 deg.C./30 min.

Etch TiW 1 in fresh 30% hydrogen peroxide 25 deg.C., 15-20 min. for approximate 0.25 micron undercut. Do not agitate etch. Specific etch rate will depend on TiW 1 background doping and thickness. Rinse 30 sec., blow dry nitrogen. Bake 90 deg.C./10 min.

Load substrate 5 in evaporator and deposit approximately 20 nm titanium 3. Use point source, no rotation, and approximately 20 in. minimum throwing distance. Liftoff excess titanium 3 using 50% acetone/isopropanol mixture. Ultrasound agitation should not be required, but if necessary use sparingly as it creates metal debris.

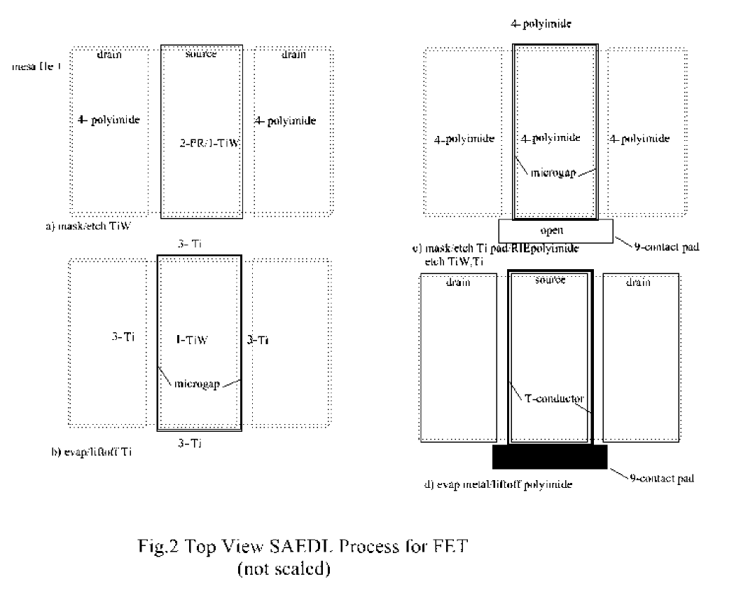

Re-spin/re-mask substrate 5 to open up contact pad 9 (see FIG. 2c,d). Note that in this embodiment the field titanium 3 has been cleared using (eg. 20:1 BOE). In this case, the substrate 5 should be well rinsed to prevent any possible fluorine diffusion.

In another embodiment, depending on desired device geometry, it is possible to have a center pad of titanium 3 surrounded by a field of TiW 1 (FIG. 2b as drawn shows center pad TiW 1 surrounded by field Ti 3). This variation involves reversing original TiW 1 etch mask polarity from opaque to clear for positive PR 2 (FIG. 2a as drawn shows clear center pad PR 2 covering etched TiW 1 for alignment clarity). In this case, the contact pad 9 opening shown in (FIG. 2c) could be etched in hydrogen peroxide (TiW 1).

In yet another embodiment, depending on desired device geometry, it is possible to liftoff additional titanium 3 metal to selectively mask polyimide 4 surface and prevent localized etching.

Load substrate 5 in plasma etcher to remove exposed polyimide 4. In preferred embodiment, the plasma etcher should permit independent biasing of substrate 5 and incident ion flux for best profile 7 control and to minimize substrate 5 damage. However, RF diode system is acceptable, and can provide good throughput.

The initial stage plasma etch is performed in plasma mode at relatively high pressure (eg. 0.5 to 2 torr oxygen) to widen gap 7. It is believed the polyimide gap 7 develops a re-entrant profile to assist subsequent liftoff.

The second stage plasma etch is done in low pressure anistropic mode (eg. 5-10 millitorr oxygen). Care should be taken to keep ion energy at a level commensurate with low damage (eg. 50-100 ev as substrate 5 surface is approached. In practice, it has been found that these conditions do not degrade GaAs FET current with extended over-etching. The etch profile 7 also remains anisotropic without requiring gas additions for sidewall passivation. However, this may not be the case for higher substrate 5 temperatures in high density plasma etchers.

Plasma etch recipe calibration can be performed by monitoring FET current after brief wet chemical recess etch near wafer edge. TiW/Ti 1,3 masking layer may be partially or completely removed depending on substrate 5 etchant and exposure time.

In another embodiment of invention, wet chemical or plasma etch of substrate 5 can be combined with removal of TiW/Ti 1,3 mask layer.

In yet another embodiment of invention, alternate materials may be substituted for TiW/Ti 1,3 layers to provide selectivity with substrate 5 etchant.

In (FIG. 1d, FIG. 2c) TiW/Ti 1,3 mask is cleared in hydrogen peroxide, rinsed water, and then brief dip in 20:1 BOE, followed by thorough rinse, blow dry, 80 deg.C./10 min. bake.

Load substrate in vacuum evaporator and deposit T-shape conductor 8 metal paying attention to proper liftoff geometry. Remove from evaporator and bake substrate 5 approximately 150 deg. C./15 min. in air to improve interfacial adhesion and metal diffusion barrier properties. Liftoff metal by soaking in 80 deg.C. N-Methyl-2-Pyrrolidone (NMP). Use fresh solvent, keep covered to prevent water absorption, and do not re-use small volumes.

FIGS. 1,2 illustrate embodiments of basic SAEDL technique applied to liftoff T-shape conductor, and applied specifically to Field Effect Transistor (FET) unit cell, respectively.

In another embodiment of SAEDL technique not specifically indicated in FIG. 1 for clarity, but apparent to those skilled in the art, is the fabrication of plated T-shape structures similar to 8. In this variant, the addition of a thin plating electrode underlying polyimide layer 4 would allow electroplated metal to fill isotropic/anisotropic etched gap 7.

Note that electroplated metal would naturally widen once above polyimide 4 surface without requiring an initial isotropic polyimide 7 etch. Also, to those skilled in the art, it is possible to electroless plate a similar T-shape conductor into gap 7. This can be accomplished with said thin plating electrode or by pre-sensitizing substrate 5 surface prior to polyimide 4 application to catalyze electroless plating reaction.

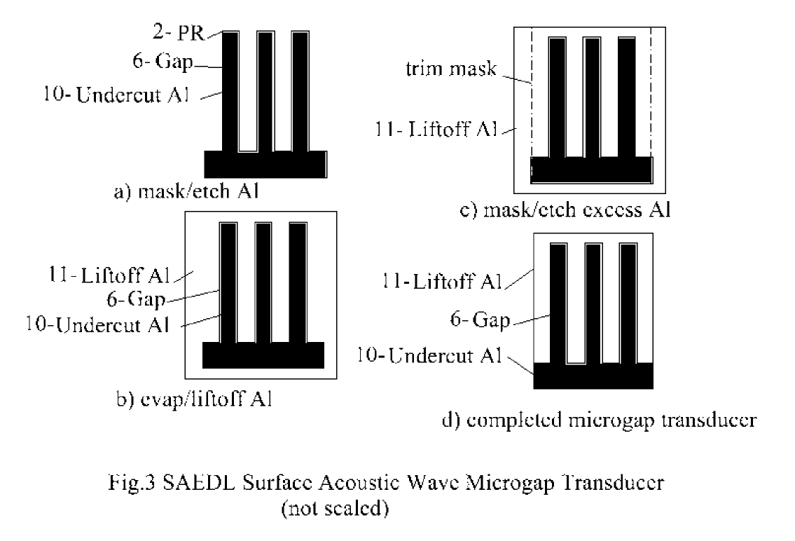

FIG. 3 illustrates another embodiment example of the SAEDL technique used to fabricate a Surface Acoustic Wave (SAW) transducer. Piezoelectric quartz has a relatively weak electrical-acoustic coupling coefficient, and aluminum metal is well matched in terms of acoustic impedance. However, the topographical discontinuity of placing many electrode fingers on quartz surface can lead to passband ripple and acoustic scattering loss. By using relatively thin aluminum 10,11 (eg. 50-100 nm) and decreasing the transducer line—space ratio, one can reduce these unwanted reflections. This geometry also favors harmonic generation for high frequency operation.

Note especially in this application that SAEDL technique is defect tolerant with respect to electrical shorting between small gaps that is difficult to achieve by standard techniques. A void in PR 2 (FIG. 3) will result in unwanted localized etching of undercut aluminum layer 10, but still result in a discontinuity with liftoff aluminum 11. Conversely, a dirt particle or undeveloped area in PR 2 will prevent localized etching of undercut aluminum 10, but also cause liftoff of aluminum layer 11, thus maintaining a discontinuity.

Interference lithography (IL) and nano-imprint techniques can rapidly generate extremely fine features over a large field. However, the electrical interconnection of such fine scale features using slower e-beam or focused ion beam writing methods poses a severe constraint. Alignment and random grating defects also pose a serious challenge.

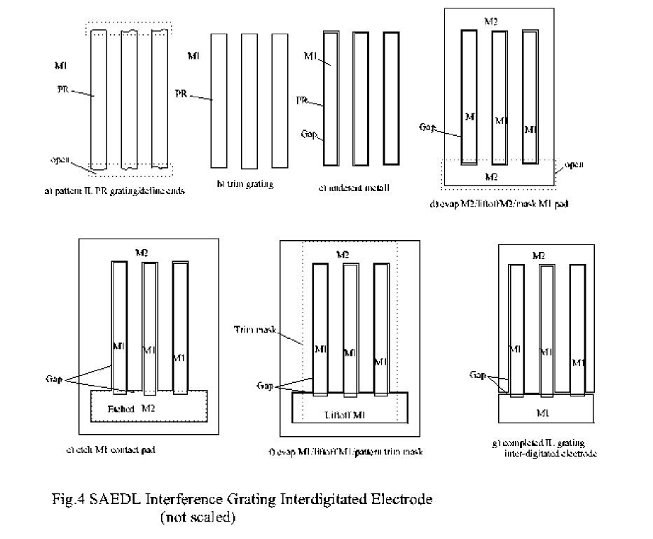

FIG. 4 illustrates a method of using SAEDL technique to interconnect such grating elements. It capitalizes on SAEDL defect tolerance and utilizing the etchant selectivity of two different metals (M1,M2). The grating periphery normal to grating lines is first trimmed to form sharp edge as shown in FIGS. 4a,b. One possibility for undercut metal M1 might consist of 30 nm Al—Cu overcoated with 5 nm TiW or Ti to reduce reflectivity. M2 might consist of evaporated 5 nm Ti 25 nm Cu. Evaporated M1 to form contact pad might consist of 5 nm Ti 25 nm Al—Cu.

Within scope of this invention it is not feasible to list all possible embodiments pertaining to masking layers, planarizing layers, substrate materials, and layers grown thereon. The listed examples and comments have been presented to illustrate the general utility of the basic SAEDL technique to those skilled in the art of microfabrication.

What is claimed is:

1. A method of fabricating a sub-micron lithographic mask consisting of:
depositing a titanium-tungsten alloy layer onto a substrate;
patterning a photoresist layer atop said titanium -tungsten layer;
wet chemical etching said titanium-tungsten layer to generate a sub-micron undercut beneath said photoresist layer;
vacuum evaporating a titanium layer onto said substrate;
removing unwanted said titanium layer by solvent liftoff dissolution of said photoresist.

2. The method of claim 1 whereby said titanium-tungsten alloy layer is deposited onto a organic polyimide layer coated substrate.

3. The method of claim 1 whereby said titanium-tungsten alloy layer is deposited onto a thermoset organic polymer or co-polymer layer.

4. The method of claim 1 whereby said titanium-tungsten alloy layer is deposited onto a thermoplastic organic polymer or co-polymer layer.

5. The method of claim 4 whereby said thermoplastic layer has been cross linked by chemical, heat, or radiation exposure.

6. The method of claim 1 whereby said titanium-tungsten alloy layer is deposited onto an inorganic layer coated substrate, said inorganic layer comprised of elements or associated compounds consisting of; aluminum, silicon, gallium, germanium, arsenic, cadmium, indium.

7. The method of claim 1 whereby said titanium-tungsten alloy and titanium layer, are replaced by; aluminum, silicon, vanadium, nickel, germanium, silicon monoxide, silicon dioxide, silicon nitride.

8. A method of fabricating a sub-micron gap inter-digitated electrode consisting of: depositing an electrically conducting metal onto a piezoelectric or ferroelectric substrate, or piezoelectric or ferroelectric layer on said substrate;
patterning a photoresist layer atop said metal;
wet chemical etching said metal to generate a sub-micron undercut beneath said photoresist layer;
vacuum evaporating an electrically conducting metal onto said layer or substrate;
removing unwanted said metal by solvent liftoff dissolution of said photoresist;
patterning and etching said interdigitated transducer to remove excess metal.

9. The method of claim 8 whereby said substrate is comprised of lithium niobate, lithium tantalate, or quartz.

10. The method of claim 8 whereby said metal conductor is comprised of following elements and respective alloys; aluminum, copper, nickel, tungsten, titanium, molybdenum, manganese, gold, silver, high temperature superconductors.

11. The method of claim 10 whereby said sub-micron gap interdigitated electrode structure is deposited on semiconducting or insulating substrate, and said electrode structure offering lithographic defect robustness against electrical shorting.

12. The method of claim 8 whereby the patterning of said photoresist layer is performed using interference lithography or nano-imprinting.

13. The method of claim 10 whereby said inter-digitated electrode structure is comprised of two different metal elements or alloys which exhibit etch selectivity with respect to each other.
